(19) United States
(12) Patent Application Publication
(10) Pub. No.: US 2024/0079336 A1
(43) Pub. Date: Mar. 7, 2024

(54) SEMICONDUCTOR PACKAGE

(71) Applicant: Samsung Electronics Co., Ltd., Suwon-si (KR)

(72) Inventors: Hyun CHUNG, Suwon-si (KR); Young Lyong Kim, Suwon-si (KR); In Hyo Hwang, Suwon-si (KR)

(73) Assignee: Samsung Electronics Co., Ltd., Suwon-si (KR)

(21) Appl. No.: 18/236,190

(22) Filed: Aug. 21, 2023

(30) Foreign Application Priority Data
Sep. 5, 2022 (KR) 10-2022-0111854

(51) Int. Cl. H01L 23/538; H01L 23/00; H01L 23/31; H01L 25/065

(52) U.S. Cl. CPC H01L 23/5381; H01L 23/3128; H01L 23/5383; H01L 24/16; H01L 24/32; H01L 24/73; H01L 25/0655; H01L 2224/16225; H01L 2224/32145; H01L 2224/73253

(57) ABSTRACT

Provided is a semiconductor package. The semiconductor package includes a redistribution line structure comprising a plurality of redistribution line patterns; a first semiconductor chip and a second semiconductor chip on the redistribution line structure and spaced apart from each other; a bridge structure between the first semiconductor chip, the second semiconductor chip, and the redistribution line structure and comprising a plurality of connection wiring patterns configured to electrically connect the first semiconductor chip to the second semiconductor chip; and a molding layer surrounding a sidewall of the bridge structure and filled between the first semiconductor chip, the second semiconductor chip, and the redistribution line structure and between the first semiconductor chip and the second semiconductor chip, wherein lowermost surfaces of the plurality of connection wiring patterns are above uppermost surfaces of the plurality of redistribution line patterns.

### CROSS-REFERENCE TO RELATED APPLICATION

This application is based on and claims priority under 35 U.S.C. § 119 to Korean Patent Application No. 10-2022-0111854 filed on Sep. 5, 2022 in the Korean Intellectual Property Office, the contents of which in its entirety are herein incorporated by reference.

### BACKGROUND

### 1. Field

The disclosure relates to a semiconductor package.

### 2. Description of Related Art

A semiconductor package is provided to implement an integrated circuit chip to qualify for use in electronic products. The semiconductor package is typically configured such that a semiconductor chip is mounted on a printed circuit board (PCB) and bonding wires or bumps are used to electrically connect the semiconductor chip to the PCB. Various techniques for improving reliability of semiconductor packages and reducing sizes of semiconductor packages have been studied with the development of the electronic industry.

For a semiconductor package including a plurality of semiconductor chips, the more semiconductor chips the semiconductor package covers, the larger size the semiconductor package has. As a size of a semiconductor package becomes larger, the semiconductor package may be vulnerable to stress generated due to a mismatch of coefficients of thermal expansion among individual components constituting the semiconductor package. Such stress may cause defects such as cracks in a semiconductor package, thereby decreasing reliability of the semiconductor package.

### SUMMARY

Aspects of the disclosure provide a semiconductor package having improved product reliability.

However, aspects of the disclosure are not restricted to those set forth herein. The above and other aspects of the disclosure will become more apparent to one of ordinary skill in the art to which the disclosure pertains by referencing the detailed description of the disclosure given below.

In accordance with an aspect of the disclosure, a semiconductor package includes a redistribution line structure including a plurality of redistribution line patterns; a first semiconductor chip and a second semiconductor chip on the redistribution line structure and spaced apart from each other; a bridge structure between the first semiconductor chip, the second semiconductor chip, and the redistribution line structure, the bridge structure including a plurality of connection wiring patterns configured to electrically connect the first semiconductor chip to the second semiconductor chip; and a molding layer surrounding a sidewall of the bridge structure and filled between the first semiconductor chip, the second semiconductor chip, and the redistribution line structure and between the first semiconductor chip and the second semiconductor chip, wherein lowermost surfaces of the plurality of connection wiring patterns are above uppermost surfaces of the plurality of redistribution line patterns.

In accordance with an aspect of the disclosure, a semiconductor package includes a molding layer having a first surface and a second surface opposite to the first surface, the molding layer including a first trench and a second trench on the first surface and a third trench on the second surface; a redistribution line structure on the second surface of the molding layer; a first semiconductor chip in the first trench; a first pillar, in the molding layer, configured to electrically connect the first semiconductor chip to the redistribution line structure; a second semiconductor chip in the second trench; a second pillar, in the molding layer, configured to electrically connect the second semiconductor chip to the redistribution line structure; a bridge structure in the third trench; and a connection pillar, in the molding layer, in contact with the first semiconductor chip and the bridge structure and in contact with the second semiconductor chip and the bridge structure.

In accordance with an aspect of the disclosure, a semiconductor package includes a redistribution line structure; a first semiconductor chip on the redistribution line structure; a second semiconductor chip on one side of the first semiconductor chip on the redistribution line structure; a third semiconductor chip on another side of the first semiconductor chip on the redistribution line structure; a first bridge structure, in a first region between the redistribution line structure, the first semiconductor chip, and the second semiconductor chip, configured to electrically connect the first semiconductor chip to the second semiconductor chip; a second bridge structure, in a second region between the redistribution line structure, the first semiconductor chip, and the third semiconductor chip, configured to electrically connect the first semiconductor chip to the third semiconductor chip; and a molding layer, on the redistribution line structure, configured to be filled in the first region and the second region, and between adjacent ones of the first semiconductor chip, the second semiconductor chip, and the third semiconductor chip, wherein the first bridge structure and the second bridge structure are insulated from the redistribution line structure.

It should be noted that the effects of the disclosure are not limited to those described above, and other effects of the disclosure will be apparent from the following description.

### BRIEF DESCRIPTION OF DRAWINGS

The above and other aspects and features of the disclosure will become more apparent by describing in detail example embodiments thereof with reference to the attached drawings, in which:

FIG. 1 is a plan view of a semiconductor package according to some embodiments;

FIG. 2 is a cross-sectional view taken along line I-I of FIG. 1;

FIG. 3 is an enlarged view of portion R1 of FIG. 1;

FIG. 4 is an enlarged view of portion R2 of FIG. 1;

FIGS. 5 to 8 are cross-sectional views of a semiconductor package according to some embodiments;

FIGS. 9 to 13 are views illustrating intermediate stages of manufacture, provided to explain a method of manufacturing a semiconductor package according to some embodiments; and

FIGS. 14 to 18 are plan views of a semiconductor package according to some embodiments.

### DETAILED DESCRIPTION OF EMBODIMENTS

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Like numerals refer to like elements throughout.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

For the sake of brevity, conventional elements to semiconductor devices may or may not be described in detail herein for brevity purposes.

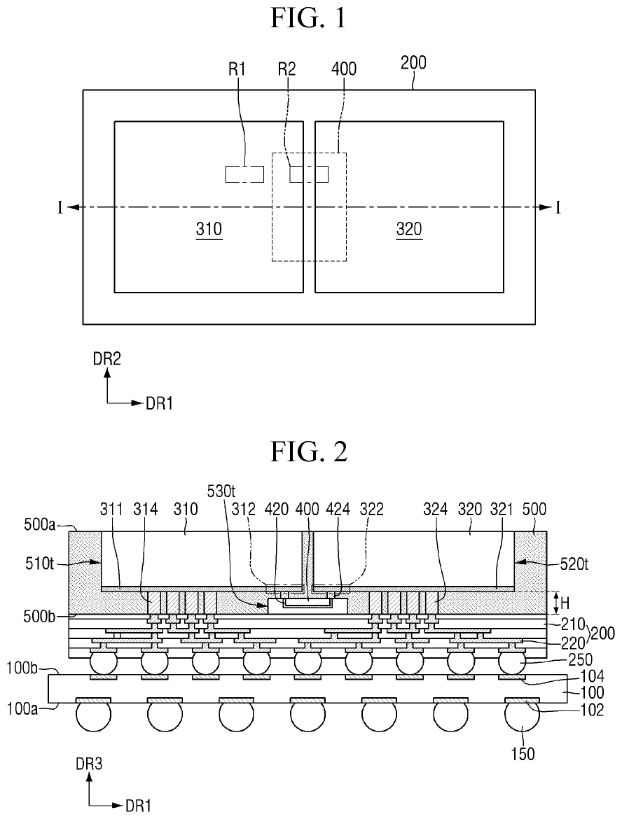

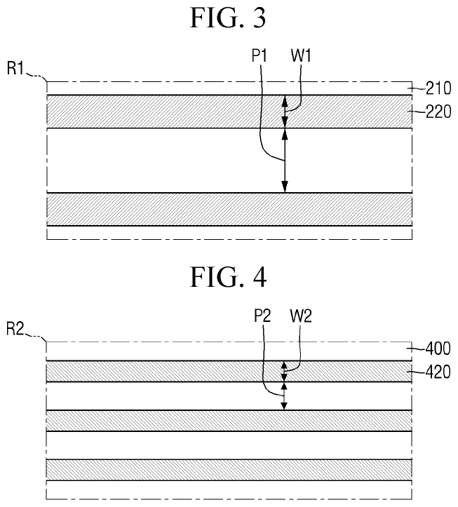

FIG. 1 is a plan view of a semiconductor package according to some embodiments. FIG. 2 is a cross-sectional view taken along line I-I of FIG. 1. FIG. 3 is an enlarged view of portion R1 of FIG. 1. FIG. 4 is an enlarged view of portion R2 of FIG. 1. FIG. 3 is a plan view for describing a redistribution line pattern 220 and FIG. 4 is a plan view for describing a connection wiring pattern 420.

Referring to FIGS. 1 and 2, a semiconductor package according to some embodiments may include a substrate 100, a redistribution line structure 200, a first semiconductor chip 310, a second semiconductor chip 320, a bridge structure 400, and a molding layer 500.

The substrate 100 may be a substrate for a semiconductor package. The substrate 100 may be, for example, a printed circuit board (PCB), a ceramic substrate, a tape wiring board, or the like. When the substrate 100 is a PCB, the package substrate 100 may be made of at least one material selected from phenol resin, epoxy resin, and polyimide. For example, the substrate 100 may include at least one material selected from FR4, tetrafunctional epoxy, polyphenylene ether, epoxy/polyphenylene oxide, bismaleimide triazine (BT), thermount, cyanate ester, polyimide, and liquid crystal polymer.

The substrate 100 may extend in each of a first direction DR1 and a second direction DR2. The first direction DR1 and the second direction DR2 may be parallel to an upper surface of the substrate 100. The second direction DR2 may intersect the first direction DR1. For example, the second direction DR2 may be perpendicular to the first direction DR1. A third direction DR3 may be perpendicular to the upper surface of the substrate 100. The third direction DR3 may intersect the first direction DR1 and the second direction DR2. Here, an upper surface and a lower surface may be determined based on the third direction DR3.

The substrate 100 may include a first substrate pad 102 and a second substrate pad 104. The first substrate pad 102 may be positioned on a lower surface 100a of the substrate 100. The second substrate pad 104 may be disposed on an upper surface 100b of the substrate 100. Although not shown in the drawings, a solder resist layer which exposes at least a portion of the first substrate pad 102 may be further disposed on the lower surface 100a of the substrate 100, and a solder resist layer which exposes at least a portion of the second substrate pad 104 may be further disposed on the upper surface 100b of the substrate 100. The first substrate pad 102 and the second substrate pad 104 may be electrically connected to each other through internal wiring of the substrate 100.

The first substrate pad 102 and the second substrate pad 104 may include a metal material, for example, at least one metal of copper (Cu), aluminum (Al), nickel (Ni), silver (Ag), gold (Au), platinum (Pt), tin (Sn), Lead (Pb), titanium (Ti), chromium (Cr), palladium (Pd), indium (In), zinc (Zn) and carbon (C), or an alloy containing two or more metals.

A first connection terminal 150 may be disposed on the first substrate pad 102 of the substrate 100. The first connection terminal 150 may be electrically connected to the first substrate pad 102. The substrate 100 may be mounted on a main board or the like of an electronic device by way of the first connection terminal 150. The first connection terminal 150 is, for example, a solder bump, but is not limited thereto. The first connection terminal 150 may have various shapes, such as a land, a ball, a pin, and a pillar.

The redistribution line structure 200 may be disposed on the substrate 100. The redistribution line structure 200 may be disposed on the upper surface 100b of the substrate 100. The redistribution line structure 200 may include a plurality of redistribution line insulating layers 210 and a plurality of redistribution line patterns 220.

The plurality of redistribution line insulating layers 210 may be stacked in the third direction DR3. The plurality of redistribution line insulating layers 210 may include at least one of, for example, silicon oxide, silicon nitride, silicon oxynitride, a low-k material having a dielectric constant lower than silicon oxide, or a photo imageable dielectric (PID) such as polyimide.

The plurality of redistribution line patterns 220 may be disposed in the plurality of redistribution line insulating layers 210. Each of the redistribution line patterns 220 may be disposed in a respective one of the redistribution line insulating layers 210. The redistribution line patterns 220 disposed in one redistribution line insulating layer 210 may be spaced apart from each other in the first direction DR1 and the second direction DR2.

The redistribution line pattern 220 may include a plurality of wiring layers positioned at different levels to form a multilayer structure, and vias extending in the third direction DR3 in the redistribution line insulating layer 210 to mutually connect the plurality of wiring layers to each other. A width of each of the vias may decrease toward, for example, the bridge structure 400.

The redistribution line pattern 220 may include a metal material, for example, tungsten (W), aluminum (Al), nickel (Ni), or copper (Cu), but is not limited thereto.

A second connection terminal 250 may be disposed between the substrate 100 and the redistribution line structure 200. The second connection terminal 250 may be disposed between the second substrate pad 104 and the lowermost redistribution line pattern 220 in the third direction DR3. The second connection terminal 250 may be electrically connected to the second substrate pad 104 and the redistribution line pattern 220. Accordingly, the substrate 100 may be electrically connected to the redistribution line structure 200.

The second connection terminal 250 may be a solder bump formed of a low melting point metal, for example, tin (Sn) or a tin alloy, but is not limited thereto. The second connection terminal 250 may have various shapes, such as a land, a ball, a pin, and a pillar. The second connection terminal 250 may be formed as a single layer or a multilayer. When the second connection terminal 250 is formed as a single layer, the second connection terminal 250 may include, for example, tin-silver (Sn—Ag) solder or copper (Cu). When the second connection terminal 250 is formed as a multilayer, the second connection terminal 250 may include, for example, a copper (Cu) pillar and solder.

The number, an interval, a dispositional form, and the like, of the first and second connection terminals 150 and 250 are not limited, but may vary widely depending on the design.

The first semiconductor chip 310 and the second semiconductor chip 320 may be mounted in the redistribution line structure 200. The first semiconductor chip 310 and the second semiconductor chip 320 may be spaced apart from each other and may be disposed on the upper surface of the redistribution line structure 200. For example, the first semiconductor chip 310 and the second semiconductor chip 320 may be spaced apart from each other in the first direction DR1.

In some embodiments, a thickness of the first semiconductor chip 310 in the third direction DR3 may be substantially equal to a thickness of the second semiconductor chip 320 in the third direction DR3.

The first semiconductor chip 310 may have a first semiconductor device layer 311 disposed on a lower surface thereof. The second semiconductor chip 320 may have a second semiconductor device layer 321 disposed on a lower surface thereof. Each of the first and second semiconductor device layers 311 and 321 may face the redistribution line structure 200 with a portion of the molding layer 500 therebetween.

The first and second semiconductor device layers 311 and 321 may each include various microelectronic devices, for example, a metal-oxide-semiconductor field effect transistor (MOSFET) such as a complementary metal-insulator-semiconductor (CMOS) transistor, a system large scale integration (system LSI), a flash memory, a dynamic random access memory (DRAM), a static RAM (SRAM), an electrically erasable programmable read-only memory (EEPROM), a phase-change RAM (PRAM), a magnetic RAM (MRAM), a resistive RAM (RERAM), an image sensor, such as a CMOS imaging sensor (CIS), a micro-electro-mechanical system (MEMS), an active device, a passive device, and the like.

The first semiconductor chip 310 may be a logic semiconductor chip. For example, the first semiconductor chip 310 may be an application processor (AP) chip such as a central processing unit (CPU), a graphic processing unit (GPU), a field-programmable gate array (FPGA), a digital signal processor, an encryption processor, a microprocessor, or a microcontroller, application-specific IC (ASIC) or the like, but is not limited thereto.

The second semiconductor chip 320 may be a memory semiconductor chip. For example, the second semiconductor chip 320 may be a volatile memory such as a dynamic random access memory (DRAM) or a static random access memory (SRAM), or a non-volatile memory such as a flash memory, a phase-change random access memory (PRAM), a magnetoresistive random access memory (MRAM), a ferroelectric random access memory (FeRAM), or a read-mostly memory (RMM).

For example, the first semiconductor chip 310 may be an ASIC such as a GPU, and the second semiconductor chip 320 may be a stack memory such as a high bandwidth memory (HBM). The stack memory may be in the form of a plurality of stacked integrated circuits. The stacked integrated circuits may be electrically connected to each other through a through silicon via (TSV) or the like.

The first semiconductor device layer 311 of the first semiconductor chip 310 may include a first physical region 312. The first physical region 312 may include an interface circuit such as PHY. The second semiconductor device layer 321 of the second semiconductor chip 320 may include a memory cell array. The second semiconductor device layer 321 may include a memory transistor constituting a memory circuit and a wiring layer on the memory transistor. The second semiconductor device layer 321 may include a second physical region 322. The second physical region 322 may include an interface circuit such as PHY. The first semiconductor chip 310 may transmit and receive signals to and from the second semiconductor chip 320 through the first physical region 312 and the second physical region 322.

A first pillar 314 may be disposed between the redistribution line structure 200 and the first semiconductor chip 310. The first pillar 314 may extend from the redistribution line structure 200 to the first semiconductor chip 310. The first pillar 314 may be in contact with the uppermost redistribution line pattern 220 in the third direction DR3 and the first semiconductor chip 310. The first pillar 314 may be in contact with, for example, a chip pad disposed on the first semiconductor device layer 311. The first pillar 314 may be electrically connected to the redistribution line structure 200 and the first semiconductor chip 310. Accordingly, the first semiconductor chip 310 may be electrically connected to the redistribution line structure 200 by way of the first pillar 314.

A second pillar 324 may be disposed between the redistribution line structure 200 and the second semiconductor chip 320. The second pillar 324 may extend from the redistribution line structure 200 to the second semiconductor chip 320. The second pillar 324 may be in contact with the uppermost redistribution line pattern 220 in the third direction DR3 and the second semiconductor chip 320. The second pillar 324 may be in contact with, for example, a chip pad disposed on the second semiconductor device layer 321. The second pillar 324 may be electrically connected to the second semiconductor chip 320 and the redistribution line structure 200. Accordingly, the second semiconductor chip 320 may be electrically connected to the redistribution line structure 200 by way of the second pillar 324.

The bridge structure 400 may be disposed on the upper surface of the redistribution line structure 200. The bridge structure 400 may be in contact with the redistribution line structure 200. With respect to the third direction DR3, a lower surface of the bridge structure 400 may be substantially coplanar with the upper surface of the redistribution line structure 200.

An upper surface of the bridge structure 400 may be spaced apart from the first and second semiconductor chips 310 and 320. A height of the bridge structure 400 in the third direction DR3 may be less than a height H of the first pillar 314 or the second pillar 324 in the third direction DR3. The height H of the first pillar 314 or the second pillar 324 may be, for example, 100 μm or less. The height of the bridge structure 400 in the third direction DR3 may be, for example, 100 μm or less.

The bridge structure 400 may be disposed in a region (e.g., a first region) between the redistribution line structure 200 and the first and second semiconductor chips 310 and 320. The bridge structure 400 may be disposed between the first pillar 314 and the second pillar 324.

The bridge structure 400 may overlap at least a portion of the first semiconductor chip 310 and at least a portion of the second semiconductor chip 320 in the third direction DR3. For example, the bridge structure 400 may overlap the first physical region 312 of the first semiconductor chip 310 in the third direction DR3, and may overlap the second physical region 322 of the second semiconductor chip 320 in the third direction DR3.

The bridge structure 400 may include a plurality of connection wiring patterns 420. The first and second semiconductor chips 310 and 320 may be electrically connected to each other by way of the plurality of connection wiring patterns 420.

Referring to FIGS. 3 and 4, a minimum width W2 of the connection wiring pattern 420 of the bridge structure 400 may be less than a minimum width W1 of the redistribution line pattern 220 of the redistribution line structure 200. A minimum pitch P2 of the connection wiring patterns 420 of the bridge structure 400 may be less than a minimum pitch P1 of the redistribution line patterns 220 of the redistribution line structure 200. The density of the connection wiring patterns 420 in the bridge structure 400 may be higher than the density of the redistribution line patterns 220 in the redistribution line structure 200. In some embodiments, a thickness of the connection wiring pattern 420 of the bridge structure 400 may be less than a thickness of the redistribution line pattern 220 of the redistribution line structure 200.

Referring back to FIGS. 1 and 2, a connection pillar 424 may be disposed between the redistribution line structure 200 and the first semiconductor chip 310 and between the redistribution line structure 200 and the second semiconductor chip 320. The connection pillar 424 may extend from the bridge structure 400 to the first semiconductor chip 310, and extend from the bridge structure 400 to the second semiconductor chip 320. The connection pillar 424 may be in contact with the connection wiring pattern 420 and the first semiconductor chip 310 and in contact with the connection wiring pattern 420 and the second semiconductor chip 320. The connection pillar 424 may be electrically connected to the connection wiring pattern 420 and the first semiconductor chip 310 and may be electrically connected to the connection wiring pattern 420 and the second semiconductor chip 320. Accordingly, the first semiconductor chip 310 and the second semiconductor chip 320 may be electrically connected to each other through the bridge structure 400.

The first pillar 314, the second pillar 324, and the connection pillar 424 may include the same material. The first pillar 314, the second pillar 324, and the connection pillar 424 may each include copper (Cu).

The bridge structure 400 may not be directly connected to the redistribution line structure 200. The bridge structure 400 may be insulated from the redistribution line structure 200. The connection wiring pattern 420 of the bridge structure 400 may not be in contact with the redistribution line pattern 220 of the redistribution line structure 200. The redistribution line pattern 220 may not be disposed in the bridge structure 400. The connection wiring pattern 420 and the redistribution line pattern 220 may be spaced apart from each other. The lowermost surface of the connection wiring pattern 420 in the third direction DR3 may be disposed above the uppermost surface of the redistribution line pattern 220 in the third direction DR3.

The molding layer 500 may be disposed on the redistribution line structure 200. The molding layer 500 may be disposed on the upper surface of the redistribution line structure 200. The molding layer 500 may be filled between the redistribution line structure 200 and the first and second semiconductor chips 310 and 320 and between the first and second semiconductor chips 310 and 320. The first and second pillars 314 and 324 may penetrate through the molding layer 500. The molding layer 500 may surround the first and second pillars 314 and 324.

The molding layer 500 may at least partially surround the first and second semiconductor chips 310 and 320. The molding layer 500 may surround sidewalls of the first and second semiconductor chips 310 and 320. The molding layer 500 may expose the upper surfaces of the first and second semiconductor chips 310 and 320. An upper surface of the molding layer 500 may be substantially coplanar with the upper surface of the first semiconductor chip 310 and the upper surface of the second semiconductor chip 320.

The molding layer 500 may be filled between the bridge structure 400 and the first and second pillars 314 and 324. The molding layer 500 may surround the bridge structure 400. The molding layer 500 may surround a sidewall of the bridge structure 400.

In some embodiments, the molding layer 500 may be filled between the bridge structure 400 and the first and second semiconductor chips 310 and 320. The molding layer 500 may cover the bridge structure 400. The molding layer 500 may cover the upper surface of the bridge structure 400. The connection pillar 424 may penetrate through the molding layer 500. The molding layer 500 may surround the connection pillar 424.

In other words, the molding layer 500 may have a first surface 500a and a second surface 500b opposite to the first surface 500a. The first surface 500a may be an upper surface of the molding layer 500 and the second surface 500b may be a lower surface of the molding layer 500. The redistribution line structure 200 may be disposed on the second surface 500b of the molding layer 500. The redistribution line structure 200 may be in contact with the second surface 500b of the molding layer 500.

The molding layer 500 may include a first trench 510t and a second trench 520t on the first surface 500a and a third trench 530t on the second surface 500b. The first semiconductor chip 310 may be disposed in the first trench 510t and the second semiconductor chip 320 may be disposed in the second trench 520t. The bridge structure 400 may be disposed in the third trench 530t.

The molding layer 500 may include, for example, a dielectric polymeric material such as an epoxy molding compound (EMC).

In a semiconductor package according to some embodiments, the first semiconductor chip 310 and the second semiconductor chip 320 may be electrically connected to each other through the bridge structure 400 without an interposer. In this case, since the first physical region 312 of the first semiconductor chip 310 and the second physical region 322 of the second semiconductor chip 320 overlap the bridge structure 400 in the third direction DR3, the distance between the first physical region 312 of the first semiconductor chip 310 and the second physical region 322 of the second semiconductor chip 320 may decrease. Accordingly, a semiconductor package having an enhanced data processing speed may be achieved.

In the case of a package in which the first and second semiconductor chips 310 and 320 are mounted on an interposer, the package may include a connection terminal between the interposer and the first and second semiconductor chips 310 and 320, an under-fill surrounding the connection terminal, and a molding layer on the interposer that at least partially covers the first and second semiconductor chips 310 and 320. The under-fill may be in contact with the molding layer. In this case, the semiconductor package may warp due to a difference in coefficient of thermal expansion between the under-fill and the molding layer. Also, cracks may be generated at the interface between the under-fill and the molding layer.

However, in the semiconductor package according to some embodiments, the molding layer 500 may be filled between the redistribution line structure 200 and the first and second semiconductor chips 310 and 320 without the under-fill and may surround the bridge structure 400. Accordingly, the warpage of the semiconductor package due to the difference in coefficient of thermal expansion between the under-fill and the molding layer 500 may be improved. In addition, cracks generated at the interface between the under-fill and the molding layer 500 may be prevented. Further, since an under-fill process is omitted, it is possible to simplify a fabrication method of the semiconductor package.

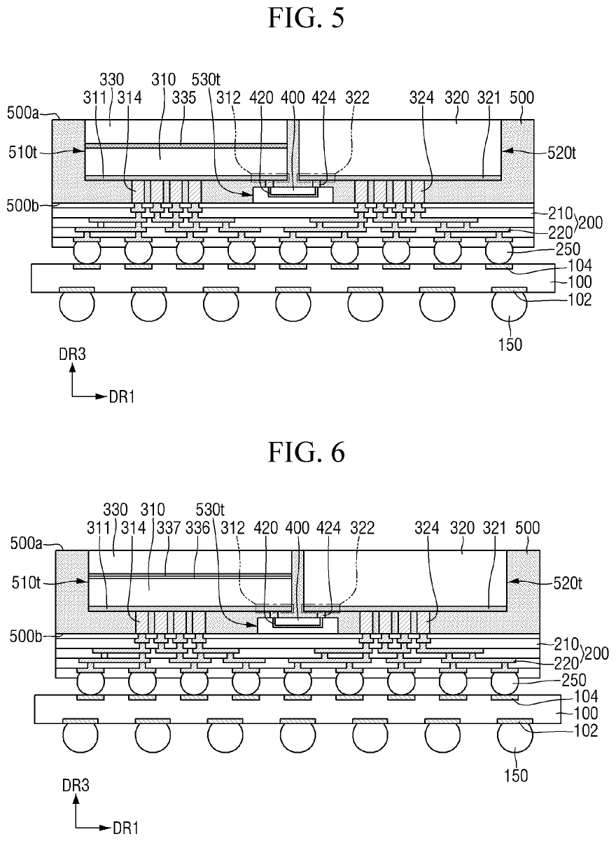

FIGS. 5 to 8 are cross-sectional views of a semiconductor package according to some embodiments. FIGS. 5 to 8 are cross-sectional views taken along line I-I of FIG. 1. For convenience of description, the following description will focus on differences from the semiconductor package described with reference to FIGS. 1 to 4.

Referring to FIGS. 5 and 6, a semiconductor package according to some embodiments may further include a dummy chip 330. A thickness of a first semiconductor chip 310 in the third direction DR3 may be less than a thickness of a second semiconductor chip 320 in the third direction DR3. The dummy chip 330 may be disposed on the first semiconductor chip 310. An upper surface of the molding layer 500 may be substantially coplanar with an upper surface of the dummy chip 330 and an upper surface of the second semiconductor chip 320.

Referring to FIG. 5, in some embodiments, the dummy chip 330 may be attached onto the first semiconductor chip 310 by an insulating layer 335. The insulating layer 335 may be disposed between the dummy chip 330 and the first semiconductor chip 310. The insulating layer 335 may include an adhesive film, such as a direct adhesive film (DAF). The DAF may include a component of a commercially available bonding agent or an adhesive. For example, the DAF may include at least one of epoxy, polyimide, acryl, or polyimide. The DAF may include at least one of acryl, vinyl acetate, an ethylene-vinyl acetate copolymer, an ethylene-acrylic acid ester copolymer, polyamide, polyethylene, polysulfone, epoxy, polyimide, a polyamide acid, a silicone phenol rubber polymer, a fluororubber polymer, a fluororesin, etc.

Referring to FIG. 6, in some embodiments, the dummy chip 330 may be attached to the first semiconductor chip 310 by an oxide-to-oxide bonding process. A first insulating layer 336 may be disposed on an upper surface of the first semiconductor chip 310 and a second insulating layer 337 may be disposed on a lower surface of the dummy chip 330. The first insulating layer 336 may be in contact with the second insulating layer 337. For example, the first insulating layer 336 and the second insulating layer 337 may each include silicon oxide. However, this is merely an example, and the materials constituting the first insulating layer 336 and the second insulating layer 337 are not limited as long as the first insulating layer 336 is attached to the second insulating layer 337. For example, the first insulating layer 336 and the second insulating layer 337 may include at least one of, for example, silicon nitride, silicon oxynitride, silicon oxycarbontride, or combinations thereof.

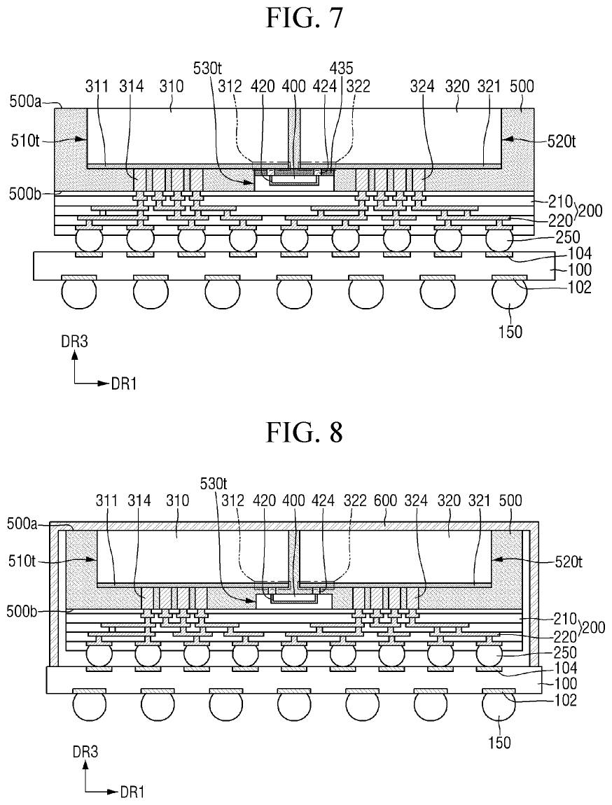

Referring to FIG. 7, the semiconductor package according to some embodiments may further include an adhesive layer 435 (e.g., a protective film). The adhesive layer 435 may be disposed between the bridge structure 400 and the first and second semiconductor chips 310 and 320. A connection pillar 424 may penetrate through the adhesive layer 435. The adhesive layer 435 may surround the connection pillar 424.

For example, a sum of a thickness of the bridge structure 400 and a thickness of the adhesive layer 435 in the third direction DR3 may be substantially equal to a height H of the first or second pillar 314 or 324 in the third direction DR3.

For example, the width of the bridge structure 400 may be substantially equal to the width of the adhesive layer 435 in the first or second direction DR1 and DR2.

The adhesive layer 435 may include a non-conducting film (NCF). For example, the adhesive layer 435 may include an epoxy-based material or a silicon-based material. The adhesive layer 435 may include a curing agent of a phenol type, an acid anhydride type, or an amine type. The adhesive layer 435 may include a thermosensitive material including an acrylic polymer, a thermoplastic material, or a UV curable material.

Referring to FIG. 8, the semiconductor package according to some embodiments may further include a heat dissipation member 600. The heat dissipation member 600 may be disposed on the substrate 100. The heat dissipation member 600 may extend from one side (e.g., one end) of the substrate 100 to the other side (e.g., the other end). The heat dissipation member 600 may cover the first and second semiconductor chips 310 and 320. The heat dissipation member 600 may surround the first and second semiconductor chips 310 and 320 and the redistribution line structure 200.

The heat dissipation member 600 may include a heat dissipation plate such as a heat slug or a heat sink.

In some embodiments, a thermal interface material layer may be further disposed between the heat dissipation member 600 and the first and second semiconductor chips 310 and 320. In some embodiments, an electromagnetic interface (EMI) shielding layer may be further disposed on an outer surface of the heat dissipation member 600. The EMI shielding layer may be electrically connected to a ground layer of the package substrate 100.

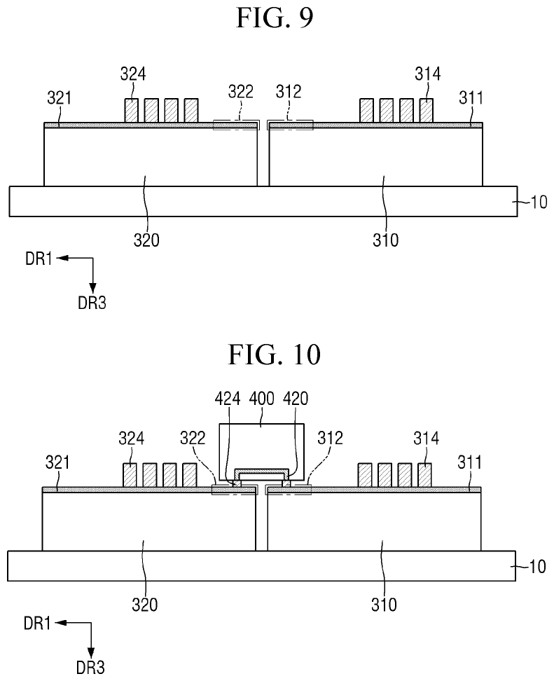

FIGS. 9 to 13 are views illustrating intermediate stages of manufacture, provided to explain a method of manufacturing a semiconductor package according to some embodiments of the disclosure.

Referring to FIG. 9, a first semiconductor chip 310 and a second semiconductor chip 320 may be formed on a carrier substrate 10. The first semiconductor chip 310 may be disposed on the carrier substrate 10 such that a surface on which a first semiconductor device layer 311 is not formed faces the carrier substrate 10. The second semiconductor chip 320 may be disposed on the carrier substrate 10 such that a surface on which a second semiconductor device layer 321 is not formed faces the carrier substrate 10.

First pillars 314 may be formed on the first semiconductor chip 310 and second pillars 324 may be formed on the second semiconductor chip 320. The first pillar 314 may be formed on the first semiconductor device layer 311 of the first semiconductor chip 310 and the second pillar 324 may be formed on the second semiconductor device layer 321 of the second semiconductor chip 320.

The carrier substrate 10 may include, for example, silicon, metal, glass, plastic, ceramic, etc.

Referring to FIG. 10, a bridge structure 400 may be formed on the first and second semiconductor chips 310 and 320. A connection pillar 424 on the bridge structure 400 may be in contact with a connection wiring pattern 420 of the bridge structure 400. The connection pillar 424 may be in contact with the first and second semiconductor chips 310 and 320.

Referring to FIG. 11, a molding layer 500 may be formed on the carrier substrate 10. The molding layer 500 may cover the first and second semiconductor chips 310 and 320 and the bridge structure 400. The molding layer 500 may cover the first and second pillars 314 and 324. The molding layer 500 may be filled between the first and second semiconductor chips 310 and 320, between the bridge structure 400 and the first and second semiconductor chips 310 and 320, between the bridge structure 400 and the first and second pillars 314 and 324, between the first pillars 314, and between the second pillars 324.

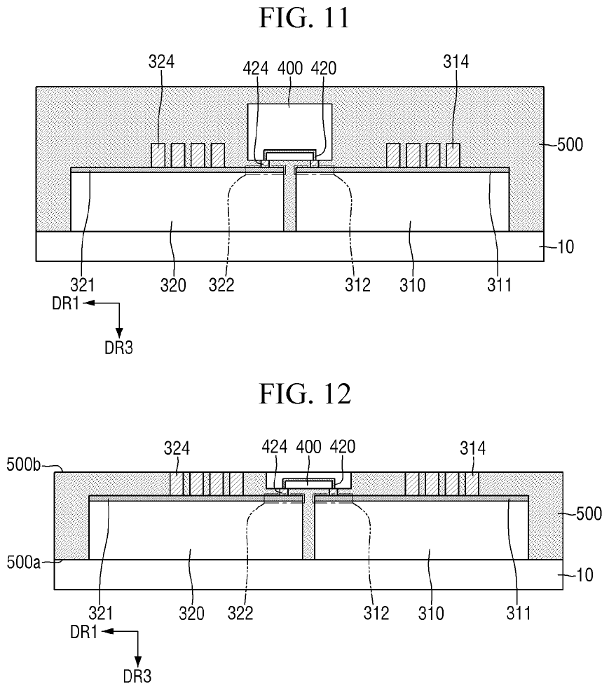

Referring to FIG. 12, the bridge structure 400 and the molding layer 500 may be removed to the extent that the first and second pillars 314 and 324 are exposed. For example, the bridge structure 400 and the molding layer 500 may be partially removed by a grinding process such as a chemical-mechanical polishing (CMP) process. Accordingly, a lower surface of the bridge structure 400, lower surfaces of the first and second pillars 314 and 324, and a lower surface of the molding layer 500 may be exposed in the third direction DR3. The lower surface of the bridge structure 400, the lower surfaces of the first and second pillars 314 and 324, and the lower surface of the molding layer 500 may be substantially coplanar with one another in the third direction DR3. The molding layer 500 may have a first surface 500a and a second surface 500b opposite to the first surface 500a. The first surface 500a may be an upper surface of the molding layer 500 in the third direction DR3 and the second surface 500b may be the lower surface of the molding layer 500 in the third direction DR3.

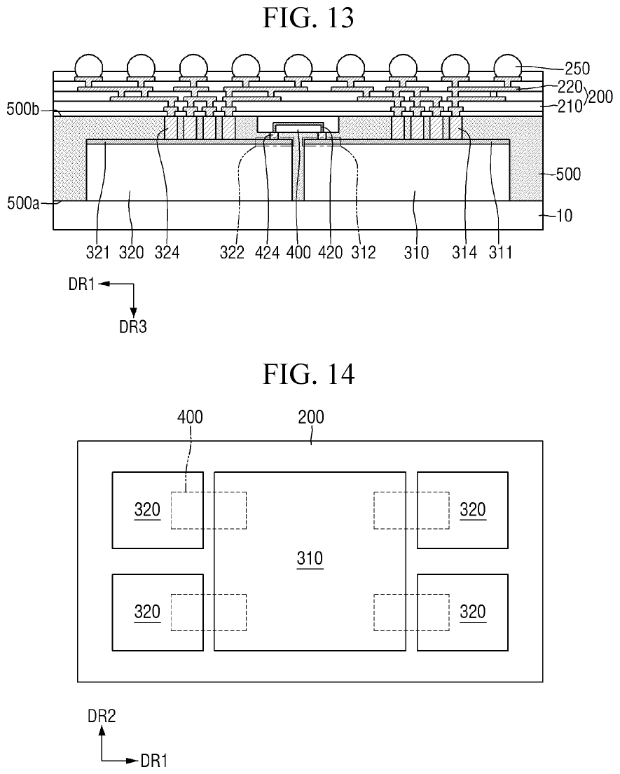

Referring to FIG. 13, a redistribution line structure 200 may be formed on the lower surface of the bridge structure 400, the lower surfaces of the first and second pillars 314 and 324, and the second surface 500b of the molding layer 500 in the third direction DR3. The redistribution line structure 200 may include a plurality of redistribution line insulating layers 210 and a plurality of redistribution line patterns 220. The redistribution line structure 200 may be formed by repeating a process of forming and patterning the redistribution line insulating layers on the lower surface of the bridge structure 400, the lower surfaces of the first and second pillars 314 and 324, and the second surface 500b of the molding layer 500 and a process of forming the redistribution line patterns 220 on the patterned redistribution line insulating layers 210. Accordingly, a width of a via of the redistribution line pattern 220 may decrease toward, for example, the bridge structure 400.

Thereafter, second connection terminals 250 may be formed on the redistribution line structure 200. The second connection terminals 250 may each be in contact with the redistribution line patterns 220. The second connection terminals 250 may be electrically connected to the redistribution line patterns 220.

Then, referring to FIG. 2, the second connection terminals 250 may be mounted on the substrate 100 and the carrier substrate 10 may be removed.

FIGS. 14 to 18 are plan views of a semiconductor package according to some embodiments. For convenience of description, the following description will focus on differences from the semiconductor package described with reference to FIGS. 1 to 13.

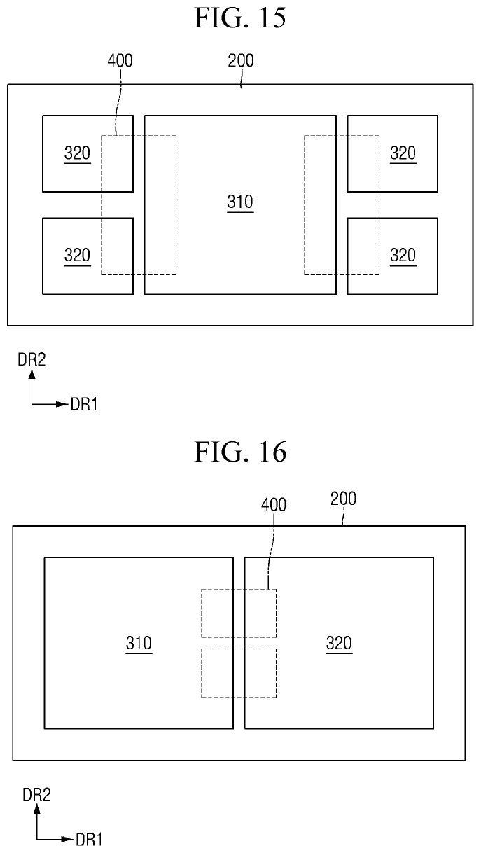

Referring to FIGS. 14 and 15, a semiconductor package according to some embodiments may further include a first semiconductor chip 310 and a plurality of second semiconductor chips 320. The first semiconductor chip 310 and the plurality of second semiconductor chips 320 may be disposed on a redistribution line structure 200. The second semiconductor chips 320 may be disposed around the first semiconductor chip 310.

For example, four second semiconductor chips 320 may be disposed around the first semiconductor chip 310. Two second semiconductor chips 320 may be disposed on each of opposite sides of the first semiconductor chip 310 in the first direction DR1. Two second semiconductor chips 320 may be disposed on one side of the first semiconductor chip 310 in the first direction DR1 and other two second semiconductor chips 320 may be disposed on the other side. That is, the first semiconductor chip 310 may be disposed between the second semiconductor chips 320. The two second semiconductor chips 320 disposed on the one side of the first semiconductor chip 310 may be spaced apart from each other in the second direction DR2, and the other two second semiconductor chips 320 disposed on the other side of the first semiconductor chip 310 may be spaced apart from each other in the second direction DR2.

A bridge structure 400 may electrically connect the first semiconductor chip 310 to one neighboring second semiconductor chip 320. The bridge structure 400 may electrically connect the first and second semiconductor chips 310 and 320 neighboring in the first direction DR1.

Referring to FIG. 14, in some embodiments, each of the second semiconductor chips 320 may be electrically connected to the first semiconductor chip 310 through the bridge structure 400. The bridge structures 400 may be disposed in respective regions corresponding to the second semiconductor chips 320, respectively. For example, a first bridge structure 400 may be disposed in a first region between the redistribution line structure, and the first semiconductor chip 310, and one of the second semiconductor chips 320, and a second bridge structure 400 may be disposed in a second region between the redistribution line structure, the first semiconductor chip 310, and another one of the semiconductor chips 320. Further, a third bridge structure 400 may be disposed in a third region between the redistribution line structure, the first semiconductor chip 310, and a third one of the second semiconductor chips 320, and a fourth bridge structure 400 may be disposed in a fourth region between the redistribution line structure, the first semiconductor chip 310, and a fourth one of the second semiconductor chips 320. The bridge structure 400 may overlap at least a portion of one second semiconductor chip 320 and at least a portion of the first semiconductor chip 310 in the third direction DR3. The bridge structure 400 may electrically connect one second semiconductor chip 320 to the first semiconductor chip 310.

Referring to FIG. 15, in some embodiments, a plurality of second semiconductor chips 320 disposed on one side or the other side of a first semiconductor chip 310 may be electrically connected to the first semiconductor chip 310 through a single bridge structure 400. The bridge structures 400 may be disposed respectively on one side and the other side of the first semiconductor chip 310. The bridge structure 400 may overlap at least a portion of each of two second semiconductor chips 320 disposed on one side of the first semiconductor chip 310 and at least a portion of the first semiconductor chip 310 in the third direction DR3. The bridge structure 400 may overlap at least a portion of each of two second semiconductor chips 320 disposed on the other side of the first semiconductor chip 310 and at least a portion of the first semiconductor chip 310 in the third direction DR3. The bridge structure 400 may electrically connect the plurality of second semiconductor chips 320 to the first semiconductor chip 310.

Referring to FIG. 16, a semiconductor package according to some embodiments may include a plurality of bridge structures 400. A first semiconductor chip 310 and a second semiconductor chip 320 may be electrically connected to each other through the plurality of bridge structures 400.

The bridge structures 400 may be spaced apart from each other between the first semiconductor chip 310 and the second semiconductor chip 320. The bridge structures 400 may be spaced apart from each other in the second direction DR2. Each of the bridge structures 400 may overlap at least a portion of the first semiconductor chip 310 and at least a portion of the second semiconductor chip 320 in the third direction DR3.

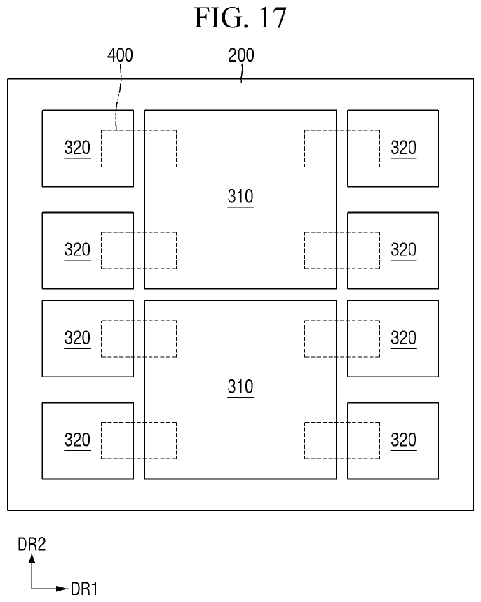

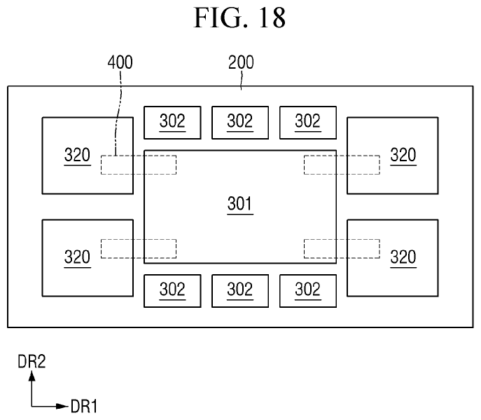

FIGS. 17 and 18 are plan views of a semiconductor package according to some embodiments. For convenience of description, the following description will focus on differences from the semiconductor package described with reference to FIG. 14.

Referring to FIG. 17, a semiconductor package according to some embodiments may further include a plurality of first semiconductor chips 310 and a plurality of second semiconductor chips 320. The plurality of first semiconductor chips 310 and the plurality of second semiconductor chips 320 may be disposed on a redistribution line structure 200.

For example, the first semiconductor chips 310 may be spaced apart from one another in the second direction DR2. Four second semiconductor chips 320 may be disposed around each of the first semiconductor chips 310.

Each of the second semiconductor chips 320 may be electrically connected to one first semiconductor chip 310 through each bridge structure 400. The bridge structures 400 may be disposed corresponding to the second semiconductor chips 320, respectively. The bridge structure 400 may overlap at least a portion of a corresponding one of the second semiconductor chips 320 and at least a portion of a corresponding one of the first semiconductor chips 310 in the third direction DR3. The bridge structure 400 may electrically connect one second semiconductor chip 320 to one first semiconductor chip 310.

Referring to FIG. 18, a semiconductor package according to some embodiments may further include a plurality of chiplets 301 and 302 and a plurality of second semiconductor chips 320. The first semiconductor chip 310 of FIG. 14 may be divided into the plurality of chiplets 301 and 302. Each of the chiplets 301 and 302 may include at least one of a process chip, a logic chip, or a memory chip.

A bridge structure 400 may electrically connect a chiplet including a physical region among the plurality of chiplets 301 and 302 to a neighboring second semiconductor chip 320. For example, a first chiplet 301 may include a physical region and a second chiplet 302 may not include a physical region. The bridge structure 400 may overlap at least a portion of the first chiplet 301 and at least a portion of the second semiconductor chip 320 in the third direction DR3. The bridge structure 400 may electrically connect the first chiplet 301 to the second semiconductor chip 320.

Alternatively, when each of the first chiplet 301 and the second chiplet 302 includes a physical region, the semiconductor package may include a bridge structure 400 configured to electrically connect the first chiplet 301 to the second semiconductor chip 320 and a bridge structure 400 configured to electrically connect the second chiplet 302 to the second semiconductor chip 320.

While the disclosure has been particularly shown and described with reference to embodiments thereof and using specific terms, these embodiments are provided so that this disclosure will fully convey the concept of the disclosure, and not for purposes of limitation. Thus, it will be obvious to one of ordinary skill in the art that various changes and other equivalents may be made therein. Therefore, the scope of the disclosure is defined not by the detailed description of the disclosure but by the appended claims.

1. A semiconductor package comprising:
a redistribution line structure comprising a plurality of redistribution line patterns;
a first semiconductor chip and a second semiconductor chip on the redistribution line structure and spaced apart from each other;
a bridge structure between the first semiconductor chip, the second semiconductor chip, and the redistribution line structure, the bridge structure comprising a plurality of connection wiring patterns configured to electrically connect the first semiconductor chip to the second semiconductor chip; and
a molding layer surrounding a sidewall of the bridge structure and filled between the first semiconductor chip, the second semiconductor chip, and the redistribution line structure and between the first semiconductor chip and the second semiconductor chip,
wherein lowermost surfaces of the plurality of connection wiring patterns are above uppermost surfaces of the plurality of redistribution line patterns.

2. The semiconductor package of claim 1, further comprising a connection pillar configured to electrically connect the first semiconductor chip to the bridge structure and electrically connect the second semiconductor chip to the bridge structure.

3. The semiconductor package of claim 2, wherein the connection pillar is in contact with the first semiconductor chip and the bridge structure and in contact with the second semiconductor chip and the bridge structure.

4. The semiconductor package of claim 2, wherein the connection pillar penetrates through the molding layer.

5. The semiconductor package of claim 2, further comprising an adhesive layer between the first semiconductor chip, the second semiconductor chip, and the bridge structure,
wherein the connection pillar penetrates through the adhesive layer.

6. The semiconductor package of claim 1, further comprising a dummy chip on the first semiconductor chip,
wherein an upper surface of the dummy chip is coplanar with an upper surface of the second semiconductor chip and an upper surface of the molding layer.

7. The semiconductor package of claim 6, further comprising an adhesive layer between the first semiconductor chip and the dummy chip.

8. (canceled)

9. The semiconductor package of claim 1, wherein a minimum pitch of the plurality of connection wiring patterns is less than a minimum pitch of the plurality of redistribution line patterns.

10. The semiconductor package of claim 1, wherein a minimum width of the plurality of connection wiring patterns is less than a minimum width of the plurality of redistribution line patterns.

11. The semiconductor package of claim 1, wherein the first semiconductor chip comprises a first physical region overlapping the bridge structure,
wherein the second semiconductor chip comprises a second physical region overlapping the bridge structure, and
wherein the first semiconductor chip transmits and receives signals to and from the second semiconductor chip through the first physical region and the second physical region.

12. (canceled)

13. A semiconductor package comprising:
a molding layer having a first surface and a second surface opposite to the first surface, the molding layer comprising a first trench and a second trench on the first surface and a third trench on the second surface;
a redistribution line structure on the second surface of the molding layer;
a first semiconductor chip in the first trench;
a first pillar, in the molding layer, configured to electrically connect the first semiconductor chip to the redistribution line structure;
a second semiconductor chip in the second trench;
a second pillar, in the molding layer, configured to electrically connect the second semiconductor chip to the redistribution line structure;
a bridge structure in the third trench; and
a connection pillar, in the molding layer, in contact with the first semiconductor chip and the bridge structure and in contact with the second semiconductor chip and the bridge structure.

14. The semiconductor package of claim 13, wherein the first pillar, the second pillar, and the connection pillar comprise a same material.

15. The semiconductor package of claim 13, wherein the redistribution line structure comprises a plurality of redistribution line patterns,
wherein the bridge structure comprises a plurality of connection wiring patterns, and
wherein the plurality of redistribution line patterns are not in contact with the plurality of connection wiring patterns.

16. The semiconductor package of claim 13, further comprising a protective film surrounding the connection pillar.

17. The semiconductor package of claim 13, further comprising a dummy chip on the first semiconductor chip,
wherein the first surface of the molding layer is coplanar with an upper surface of the dummy chip and with an upper surface of the second semiconductor chip.

18. The semiconductor package of claim 13, wherein the first pillar is in contact with the first semiconductor chip and the redistribution line structure, and
wherein the second pillar is in contact with the second semiconductor chip and the redistribution line structure.

19. A semiconductor package comprising:
a redistribution line structure;
a first semiconductor chip on the redistribution line structure;
a second semiconductor chip on one side of the first semiconductor chip on the redistribution line structure;
a third semiconductor chip on another side of the first semiconductor chip on the redistribution line structure;
a first bridge structure, in a first region between the redistribution line structure, the first semiconductor chip, and the second semiconductor chip, configured to electrically connect the first semiconductor chip to the second semiconductor chip;
a second bridge structure, in a second region between the redistribution line structure, the first semiconductor chip, and the third semiconductor chip, configured to electrically connect the first semiconductor chip to the third semiconductor chip; and
a molding layer, on the redistribution line structure, configured to be filled in the first region and the second region, and between adjacent ones of the first semiconductor chip, the second semiconductor chip, and the third semiconductor chip,
wherein the first bridge structure and the second bridge structure are insulated from the redistribution line structure.

20. The semiconductor package of claim 19, wherein the first semiconductor chip comprises a logic semiconductor chip, and
wherein the second semiconductor chip and the third semiconductor chip comprise memory semiconductor chips.

21. The semiconductor package of claim 19, further comprising:
a fourth semiconductor chip on the one side of the first semiconductor chip on the redistribution line structure;
a fifth semiconductor chip on the other side of the first semiconductor chip on the redistribution line structure;
a third bridge structure, in a third region between the redistribution line structure, the first semiconductor chip, and the fourth semiconductor chip, configured to electrically connect the first semiconductor chip to the fourth semiconductor chip; and
a fourth bridge structure, in a fourth region between the redistribution line structure, the first semiconductor chip, and the fifth semiconductor chip, configured to electrically connect the first semiconductor chip to the fifth semiconductor chip,
wherein the third bridge structure and the fourth bridge structure are insulated from the redistribution line structure.

22. The semiconductor package of claim 19, further comprising:
a fourth semiconductor chip disposed on the one side of the first semiconductor chip on the redistribution line structure; and
a fifth semiconductor chip disposed on the other side of the first semiconductor chip on the redistribution line structure,
wherein the first bridge structure is configured to electrically connect the first semiconductor chip to the fourth semiconductor chip and the second bridge structure is configured to electrically connect the first semiconductor chip to the fifth semiconductor chip.
